(19) United States
(12) Patent Application Publication
(10) Pub. No.: US 2017/0226640 A1
(43) Pub. Date: Aug. 10, 2017

(54) SUBSTRATE WITH AMORPHOUS, COVALENTLY-BONDED LAYER AND METHOD OF MAKING THE SAME

(71) Applicant: 3M INNOVATIVE PROPERTIES COMPANY, St. Paul, MN (US)

(72) Inventors: Biljana Mikijelj, Cerritos, CA (US); Muhammad Z. Nawaz, North Tustin, CA (US); Moses M. David, Woodbury, MN (US)

(21) Appl. No.: 15/501,044

(22) PCT Filed: Jul. 31, 2015
(86) PCT No.: PCT/US2015/043160

§ 371 Date: Feb. 1, 2017

Related U.S. Application Data
(60) Provisional application No. 62/032,109, filed on Aug. 1, 2014.

(51) Int. Cl. C23C 16/50; C23C 16/30; B24B 37/10; C23C 16/56

(52) U.S. Cl. CPC C23C 16/50; C23C 16/56; C23C 16/30; B24B 37/107

(57) ABSTRACT

An article that includes a substrate and an amorphous, covalently-bonded layer on the surface of the substrate. The substrate may be a crystalline ceramic and/or may have a surface with a first surface roughness (Ra) of at least 100 angstroms, and the amorphous, covalently-bonded layer has a second surface roughness (Ra) of up to 15 angstroms. The substrate may have a dimension of at least 50 mm, and the amorphous, covalently-bonded layer may have a thickness of at least five micrometers. A method of making an article is also disclosed. The method includes forming an amorphous, covalently-bonded layer on the surface of the substrate by plasma deposition and, in some embodiments, polishing the amorphous, covalently-bonded layer to a second surface roughness (Ra) of up to 15 angstroms. The amorphous, covalently-bonded layer in the article and method includes silicon, oxygen, carbon, and hydrogen atoms.

### CROSS-REFERENCE TO RELATED APPLICATION

This application claims priority to U.S. Provisional Application No. 62/032,109, filed Aug. 1, 2014, the disclosure of which is incorporated by reference in its entirety herein.

### BACKGROUND

Amorphous, covalently-bonded coatings and films have been applied to a variety of substrates such as organic materials, polymeric films, ceramic substrates, semiconductor substrates, and metal substrates. Such coatings can be useful, for example, for modifying the surface properties of a substrate. For example, amorphous diamond-like coatings can be hard, chemically inert, corrosion resistant, and repellent to water vapor and oxygen. For some examples of diamond-like coatings on a substrate, see U.S. Pat. No. 5,609,948 (David et al.), U.S. Pat. No. 6,468,642 (Bray et al.), U.S. Pat. No. 6,696,157 (David et al.), and U.S. Pat. No. 6,878,419 (David et al.).

### SUMMARY

For certain applications (e.g., complementary metal oxide semiconductor structures), substrates are required to have an extremely smooth and flat finish. Such a smooth finish can be difficult to achieve for some otherwise useful materials. For example, polycrystalline ceramics, which have usefully high thermal conductivities and low electrical conductivities, have fine porosity and differing crystallographic orientations. When polishing polycrystalline ceramics, differences in removal rates of individual grains in the ceramic material can make it difficult to achieve the desired smoothness. In other applications, metal substrates such as copper foils can have a wide variety of surface roughness values, for example, five nanometers (nm) to 250 nm.

We have now found that amorphous, covalently-bonded layers including silicon, oxygen, carbon, and hydrogen atoms (in some embodiment, diamond-like glass) can be applied to substrates and polished using conventional methods to very low roughness, regardless of the initial roughness of the substrate.

In one aspect, the present disclosure provides an article that includes a substrate and an amorphous, covalently-bonded layer on the surface of the substrate. The amorphous, covalently-bonded layer includes silicon, oxygen, carbon, and hydrogen atoms. The surface of the substrate has a first surface roughness (Ra) of at least 100 angstroms, and the amorphous, covalently-bonded layer has a second surface roughness (Ra) of up to 15 angstroms.

In another aspect, the present disclosure provides an article that includes a substrate and an amorphous, covalently-bonded layer on the surface of the substrate. The amorphous, covalently-bonded layer includes silicon, oxygen, carbon, and hydrogen atoms and has a second surface roughness (Ra) of up to 15 angstroms. The substrate includes a crystalline ceramic. The ceramic may be a single crystal or polycrystalline ceramic. Typically, the amorphous, covalently-bonded layer is disposed directly on the crystalline ceramic substrate.

In another aspect, the present disclosure provides a method of making an article. The method includes providing a substrate having a surface, forming an amorphous, covalently-bonded layer on the surface of the substrate by plasma deposition, and polishing the amorphous, covalently-bonded layer to a second surface roughness (Ra) of up to 15 angstroms. The amorphous, covalently-bonded layer includes silicon, oxygen, carbon, and hydrogen atoms.

In useful precursor articles including a substrate and an amorphous, covalently-bonded layer that may be polished to achieve a second surface roughness (Ra) of up to 15 angstroms, the thickness of the amorphous, covalently-bonded layer before polishing may be at least 5 micrometers. Even though it is conventionally difficult to make coatings of this thickness on a substrate due to compressive stress in the coating, we have been able to achieve amorphous, covalently-bonded layers of this thickness even on relatively large substrates.

Accordingly, in another aspect, the present disclosure provides an article that includes a substrate and an amorphous, covalently-bonded layer on the surface of the substrate. The substrate has a dimension of at least 50 millimeters. The amorphous, covalently-bonded layer includes silicon, oxygen, carbon, and hydrogen atoms and has a thickness of at least 5 micrometers. The amorphous, covalently-bonded layer may be plasma deposited.

Accordingly, in another aspect, the present disclosure provides a method of making an article. The method includes providing a substrate having a surface and a dimension of at least 50 millimeters and forming an amorphous, covalently-bonded layer on the surface of the substrate by plasma deposition. The amorphous, covalently-bonded layer includes silicon, oxygen, carbon, and hydrogen atoms and has a thickness of at least 5 micrometers.

In this application, terms such as “a”, “an” and “the” are not intended to refer to only a singular entity, but include the general class of which a specific example may be used for illustration. The terms “a”, “an”, and “the” are used interchangeably with the term “at least one”. The phrases “at least one of” and “comprises at least one of” followed by a list refers to any one of the items in the list and any combination of two or more items in the list. All numerical ranges are inclusive of their endpoints and non-integral values between the endpoints unless otherwise stated (e.g. 1 to 5 includes 1, 1.5, 2, 2.75, 3, 3.8, 4, and 5, and the like).

Unless otherwise indicated, all numbers expressing quantities, ingredients, and measurement of properties used herein are to be understood as being modified in all instances by the term “about.” At the very least, and not as an attempt to limit the application of the doctrine of equivalents to the scope of the claimed embodiments, each numerical parameter should at least be construed in light of the number of reported significant digits and by applying ordinary rounding techniques.

The term “amorphous” means a substantially randomly-ordered, non-crystalline material having no x-ray diffraction peaks or having modest x-ray diffraction peaks. The amorphous layer in the articles and methods according to the present disclosure may contain an assembly of atoms to give it a short-range order but is essentially free of medium and long range ordering that lead to micro or macro crystallinity.

The terms “first” and “second” are used in this disclosure. It will be understood that, unless otherwise noted, those terms are used in their relative sense only. The designation of “first” and “second” may be applied to components of the articles and methods disclosed herein merely as a matter of convenience in the description of one or more of the embodiments. For example, for convenience the surface roughness of the substrate below the amorphous, covalently-bonded layer is referred to as the first surface roughness, and the surface roughness of the amorphous, covalently-bonded layer in the article according to the present disclosure is referred to as the second surface roughness.

As used herein, the term “plasma” means a partially ionized gaseous or fluid state of matter containing reactive species which include electrons, ions, neutral molecules, free radicals, and other excited state atoms and molecules. Visible light and other radiation are typically emitted from the plasma as the species forming the plasma relax from various excited states to lower, or ground, states. The term “plasma treatment” as used herein typically refers to plasma treatment of a substrate carried out under conditions of ion bombardment.

The term “ceramic” as used herein refers to glasses, crystalline ceramics, glass-ceramics, and combinations thereof.

The above summary of the present disclosure is not intended to describe each disclosed embodiment or every implementation of the present disclosure. The description that follows more particularly exemplifies illustrative embodiments. It is to be understood, therefore, that the drawings and following description are for illustration purposes only and should not be read in a manner that would unduly limit the scope of this disclosure.

### BRIEF DESCRIPTION OF THE DRAWINGS

The disclosure may be more completely understood in consideration of the following detailed description of various embodiments of the disclosure in connection with the accompanying drawings, in which:

FIG. 1 is a schematic side view of an embodiment of an article according to the present disclosure;

FIG. 2 illustrates a cross-section of a parallel plate apparatus suitable for forming an amorphous, covalently-bonded layer on the surface of the substrate;

FIG. 3 is a perspective view of an example of a holder useful for holding a round substrate during plasma deposition;

FIG. 4 is a micrograph taken with a scanning electron microscope of a cross-section showing an amorphous, covalently-bonded layer deposited on a silicon carbide substrate;

FIG. 5 is a micrograph taken with a scanning electron microscope showing the surface of a polished amorphous, covalently-bonded layer in an article according to the present disclosure; and

FIG. 6 is a micrograph taken with a scanning electron microscope showing the surface of a polished surface of a silicon carbide substrate.

### DETAILED DESCRIPTION

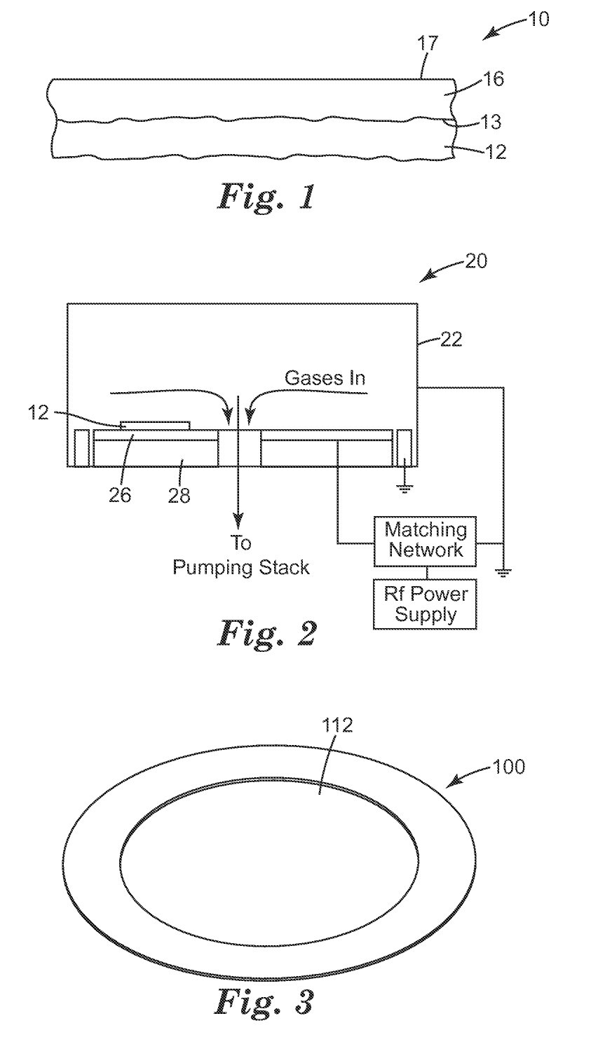

FIG. 1 is a schematic side view of an embodiment of an article 10 according to the present disclosure. Article 10 includes a substrate 12 and an amorphous, covalently-bonded layer 16 disposed on a surface 13 of substrate 12. In any embodiment of the article disclosed herein, the amorphous, covalently-bonded layer 16 may be formed directly on the surface 13 of the substrate 12.

The amorphous, covalently-bonded layer 16 includes silicon, oxygen, carbon, and hydrogen atoms. The atoms are attached to each other by covalent bonds. In some embodiments, the amorphous, covalently-bonded layer 16 includes, on a hydrogen-free basis, at least about 30 atomic percent carbon, at least about 25 atomic percent silicon, and up to about 45 atomic percent oxygen. In some embodiments, the amorphous, covalently-bonded layer contains from about 30 to about 50 atomic percent carbon. In some embodiments, the amorphous, covalently-bonded layer can include about 25 to about 35 atomic percent silicon. Also, in some embodiments, the amorphous, covalently-bonded layer includes about 20 to about 40 atomic percent oxygen. In some embodiments, the amorphous, covalently-bonded layer comprises from about 30 to about 36 atomic percent carbon, from about 26 to about 32 atomic percent silicon, and from about 35 to about 41 atomic percent oxygen on a hydrogen free basis. “Hydrogen free basis” refers to the atomic composition of a material as established by a method such as Electron Spectroscopy for Chemical Analysis (ESCA), which does not detect hydrogen even if large amounts are present in the thin films. (References to compositional percentages herein refer to atomic percents.) The compositions of these embodiments can be observed, for example, in the interior of the layer although a higher atomic percentage of oxygen may be observed at the surface 17 of layer 16.

In some embodiments, including any of the embodiments described above, other atoms may be incorporated into the amorphous, covalently-bonded layer (e.g., nitrogen, fluorine, sulfur, titanium, or copper). The presence of nitrogen may enhance resistance to oxidation but may increase electrical conductivity, which may not be desirable in certain applications. The presence of sulfur and/or titanium may enhance adhesion, and titanium may also increase diffusion barrier properties. The presence of fluorine may enhance barrier and surface properties of the amorphous, covalently-bonded layer. However, in some embodiments, the amorphous, covalently-bonded layer comprises on a hydrogen-free basis up to about one atomic percent fluorine.

In some embodiments, including any of the embodiments described above, the amorphous, covalently-bonded layer is a diamond-like glass. Carbon deposits contain substantially two types of carbon-carbon bonds: trigonal bonds (sp²) and tetrahedral bonds (sp³). While amorphous, covalently-bonded layers can include varying amounts of sp² and sp³ bonds, diamond-like glass includes a significant amount of sp³ bonds. For example, diamond-like glass typically includes at least 30% sp³ bonds, in some embodiments, approximately 50% to 90% sp³ bonds. The type and amount of intermolecular bonds are determined by infrared (IR) and nuclear magnetic resonance (NMR) spectra. Diamond-like glass can also be identified by its properties. For example, diamond-like glass may have gram atom density in a range from 0.20 to 0.28 gram atoms/cubic centimeter and a hardness in a range from 1000 to 2000 kg/mm².

In some embodiments, the amorphous, covalently-bonded layer (in some embodiments, diamond-like glass) is formed by plasma deposition, for example, under the conditions of ion bombardment. A typical reaction chamber for plasma deposition includes a capacitively coupled reactor system having two electrodes in an evacuable reaction chamber. The reaction chamber is typically partially evacuated, a radio frequency (RF) electric field is applied to the powered electrode (e.g., a plate electrode on which the substrate is placed), a gas is introduced between the electrodes and is ionized, and a plasma is established. In the RF-generated plasma, energy is coupled into the plasma through electrons. The plasma acts as the charge carrier between the electrodes. In some embodiments, the plasma may be visible as a colored cloud. The plasma is also generally thought to form an ion sheath proximate at least to the RF-powered electrode. The substrate is exposed to the reactive species within the ion sheath to form the amorphous, covalently-bonded layer on its surface. The ion sheath may appear as a darker area near the RF-powered electrode. The depth of the ion sheath normally ranges from about 1 mm to about 50 mm and depends on factors such as the type and concentration of gas used, pressure, the spacing between the electrodes, and relative size of the electrodes. For example, reduced pressures will increase the size of the ion sheath. When the electrodes have different sizes, a larger, stronger ion sheath will form around the smaller electrode. Generally, the larger the difference in electrode size, the larger the difference in the size of the ion sheaths, and increasing the voltage across the ion sheath will increase ion bombardment energy. Conveniently, the reaction chamber, which may have at least 2 to 3 times the surface area of the powered electrode, may serve as the second, grounded electrode.

Plasma, created from the gas within the reaction chamber, can be powered by an RF generator (e.g., available from Seren IPS, Inc., Vineland, N.J., Model No. R1001,) operating at a frequency in a range, for example, from 0.001 to 100 MHz). The RF generator (e.g., an oscillator) can provide power at a typical frequency in a range from 0.01 to 50 MHz, for example, 13.56 MHz or any whole number (e.g., 1, 2, or 3) multiple thereof. The power source may be connected to the apparatus via a network that serves to match the impedance of the power supply with that of the transmission line to effectively transmit RF power through a coaxial transmission line. Such matching networks are commercially available (e.g., from Advanced Energy, Fort Collins, Colo., as Rf Plasma Products Model AMN-10).

An example of an apparatus useful for plasma deposition is illustrated in FIG. 2. FIG. 2 illustrates a parallel plate apparatus 20 having a grounded chamber 22 from which air is removed by a pumping stack (not shown). The gas or gases to form the plasma are injected radially inward through the reactor wall to an exit pumping port in the center of the chamber. Substrate 12 is positioned proximate the RF-powered electrode 26. Electrode 26 is insulated from the chamber 22 by a polytetrafluoroethylene support 28.

In some embodiments, forming the amorphous, covalently-bonded layer (in some embodiments, diamond-like glass) comprises ionizing a gas comprising at least one of an organosilicon or a silane compound. In some embodiments, a gas comprising one or more organosilicon compounds is introduced into the system at a flow rate selected so that a sufficient flow is provided to establish a suitable pressure at which to carry out plasma deposition. In some embodiments, the pressure at the interior surface of the reactor is at least 100 millitorr (13.3 Pa) or 300 millitorr (40 Pa), and in some embodiments is in the range from 500 millitorr to 5000 millitorr (66.7 Pa to 667 Pa). In some embodiments, the flow density of the organosilicon compound applied is at least about 0.01 standard cubic centimeters per minute (sccm)/square cm, in some embodiments at least about 0.05 sccm/square cm, and in some embodiments at least about 0.1 sccm/square cm. Flow density is a ratio of the flow (typically in standard cubic centimeters per minute (sccm)) of the gas and the surface area of the substrate to be treated. Flow densities are typically up to about 0.30 sccm/square cm, in some embodiments up to about 0.25 sccm/square cm. For a cylindrical reactor that has an inner diameter of approximately 55 cm and a height of approximately 20 cm, the flow rates are typically from about 50 sccm to about 500 sccm. These flow densities typically refer to organosilicon compounds only (i.e., without any non-organosilicon assist gases). The organosilicon compound may be a mixture of organosilicon compounds. These pressures and flow densities may be advantageous in providing high coating densities as well as uniform and conformal coatings having a high degree of flexibility and resistance to cracking.

For plasma deposition of an amorphous, covalently-bonded layer (in some embodiments, diamond-like glass), typically elemental silicon present in the at least one organosilicon compound is present in an amount of at least about 5 atomic percent of the gas mixture. In some embodiments, the organosilicon compound comprises at least one of trimethylsilane, triethylsilane, trimethoxysilane, triethoxysilane, tetramethylsilane, tetraethylsilane, tetramethoxysilane, tetraethoxysilane, hexamethylcyclotrisiloxane, tetramethylcyclotetrasiloxane, tetraethylcyclotetrasiloxane, octamethylcyclotetrasiloxane, hexamethyldisiloxane, or bistrimethylsilylmethane. In some embodiments of the method disclosed herein, the gas comprising the organosilicon compound comprises at least one of tetramethylsilane or tetraethyoxysilane (in some embodiments, tetramethylsilane).

In some embodiments, to form an amorphous, covalently-bonded layer the gas that is ionized includes a silane compound in addition to or instead of the organosilicon compound. Useful silane compounds include SiH₄ (silicon tetrahydride), Si₂H₆ (disilane), SiClH₃ (chlorosilane), and combinations of these.

In some embodiments of the methods according to the present disclosure, the source gas includes an organosilicon compound and may further comprise an additional gas or gases. Each additional gas can be added separately or in combination with each other. If a gas is mixed along with the organosilicon compound(s), the atomic percent of silicon in the gas mixture generally is calculated based on the volumetric (or molar) flow rates of the component gases in the mixture. The source gas may, for example, further comprise at least one of argon or hydrogen. Argon normally is not incorporated into the deposited coating but enhances ion bombardment, while hydrogen may promote the formation of high packing density while providing an additional source of hydrogen in the deposited composition. Optionally, the source gas may further comprise at least one of ammonia or nitrogen. However, in some embodiments, the plasma-deposited diamond-like glass coating is substantially free of nitrogen (e.g. at most about 5 atomic percent of nitrogen (on a hydrogen free basis)), and in some embodiments, free of nitrogen. The source gas may further comprise fluorine. However, in some embodiments, the gas is free of fluorinated compounds, or the gas comprises a fluorinated compound at up to 1 molar percent of the gas. The source gas may further comprise oxygen gas. In these embodiments, the amount of oxygen gas is less than 35% on a molar basis, in particular less than 30% on a molar basis.

In some embodiments, the method according to the present disclosure includes depositing an oxygen-lean diamond-like glass coating on the substrate. In some embodiments, the atomic ratio of oxygen (O) to silicon (Si) (O:Si) in the source gas is up to 3:1, in some embodiments, up to 2.5:1, in some embodiments up to 1:1, and in some embodiments, up to 0.8:1. In some embodiments, the amount of oxygen assist gas or oxygen-containing organosilicon(s) is no more than that corresponding to 5% on an atomic basis of oxygen relative to total content of silicon on an atomic basis.

The substrate is exposed to the ion bombarded species being deposited from the plasma. The resulting reactive species within the plasma react on the surface of the substrate, forming a layer, the composition of which is controlled by the gas being ionized in the plasma. The species forming the layer can attach to the surface of the substrate by covalent bonds; therefore, in some embodiments, the amorphous, covalently-bonded layer is covalently bonded to the substrate. This may enhance the polishing of the article, for example, by improving the adhesion of the amorphous, covalently-bonded layer to the substrate and preventing it from chipping or flaking off the substrate during polishing.

Plasma deposition of a diamond-like glass coating typically occurs at a rate ranging from about 1 to about 100 nm/second. The rate will depend on conditions including, for example, pressure, power, concentration of gas, types of gases, and relative size of the electrodes. In general, the deposition rate increases with increasing power, pressure, and concentration of gas, although the rate can approach an upper limit.

In some embodiments, the substrate is placed in a holder before it is placed on the electrode during plasma deposition. This can be useful, for example, to eliminate any non-uniformity of the deposition that may occur near the edge of the substrate. An example of a substrate holder is shown in FIG. 3. In FIG. 3, substrate holder 100 is a metal plate with a recessed portion 112 where the substrate sits, and the surface of the substrate to be treated is at the same height as the plate surrounding it. The dimensions of the recessed portion 112 are generally the same as the dimensions of the substrate so that the edge of the substrate is not plasma-treated. Although the recessed portion 112 in the illustrated embodiment is round, it may be a variety of different shapes depending on the shape of the substrate to be treated. The substrate holder may be made from a variety of useful conductive materials. In some embodiments, the substrate holder is made from aluminum. In embodiments in which the substrate has an angular shape, instead of using a substrate holder as shown in FIG. 3, conductive plates (e.g., aluminum plates) can be stacked against the edges of the substrate. In these embodiments, the surface of the substrate to be treated is at the same height as the plates stacked around it.

Diamond-like glass coatings and further methods of making diamond-like glass are described in U.S. Pat. No. 6,696,157 (David et al.)

In some embodiments, the method according to the present disclosure includes polishing the amorphous, covalently-bonded layer. To polish the amorphous, covalently-bonded layer, it is typically useful for the amorphous, covalently-bonded layer to have a thickness of at least five (in some embodiments, at least 6, 7, 8, 9, or 10) micrometers. In some embodiments, plasma deposition is carried out for a period of time such that the deposited diamond-like glass coating has a thickness in the range from about 5 micrometers to about 10 micrometers. In some embodiments, the plasma deposition of amorphous, covalently-bonded layer is carried out for a period of time of at least about ten minutes, 20 minutes, or 30 minutes.

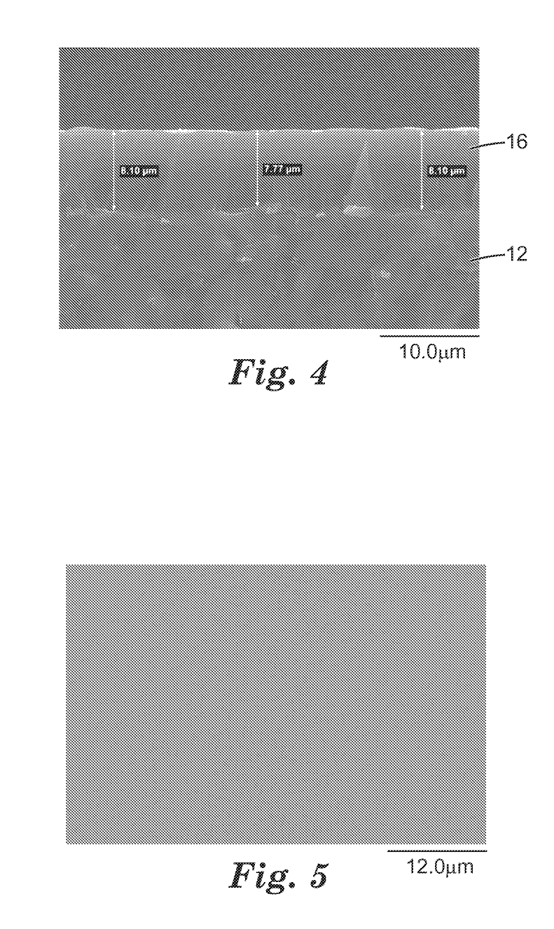

In many embodiments, the amorphous, covalently-bonded layer formed on the surface of the substrate is continuous, uniform in composition and thickness across the substrate surface, and essentially pore-free throughout when observed by scanning electron microscopy at high magnifications as shown in FIGS. 4 and 5 and described in the Examples, below. “Essentially pore-free” means that there is no visibly porosity observed by scanning electron microscopy (SEM). Any pores that may be present have a maximum dimension up to 100 nm, 75 nm, 50 nm, or 25 nm. The low porosity of the amorphous, covalently-bonded layer is evident from the SEM shown in FIG. 5, which reveals no surface porosity. We have been able to achieve amorphous, covalently-bonded layers that are uniform in composition and thickness and essentially pore-free even when the layers are relatively thick and formed on large substrates.

For large substrates (in some embodiments, substrates having a dimension of at least 50 mm) and for depositing thick amorphous, covalently-bonded layers (in some embodiments, layers at least 5 micrometers thick) it is useful to apply relatively high power densities to shorten the time necessary to achieve the desired layer dimensions. In some embodiments, the power density is greater than about 0.10 watt/square cm. Power density is a ratio of the plasma power (typically in watts) and the surface area (typically in square cm) of the powered electrode on which the substrate is placed. In some of these embodiments, the power density is greater than about 0.2, 0.4, 0.6, 0.8, 1, or 5 watts/square cm.

Plasma deposition can be carried out by plasma pulsing by turning on and off the power supply. Pulsing may be particularly useful, for example, when using high power densities to deposit thick amorphous-covalently bonded layers (e.g., at least 5 micrometers thick) on large substrates (e.g., having a dimension of at least 50 micrometers). High power densities (e.g., greater than 0.2 watt/square cm) can lead to solid particle formation in the gas phase at the edge of the ion sheath. With longer residence time in the plasma, the particles can grow in size. Pulsing minimizes the particle formation. Pulsing also prevents incorporation of particles into the amorphous, covalently-bonded layer (in some embodiments, diamond-like glass) by allowing the gas flow to flush any particles that may be formed out of the plasma chamber when the power supply is off.

During plasma deposition of an amorphous, covalently-bonded layer (in some embodiments, diamond-like glass), the temperature of the powered electrode and/or substrate is typically controlled to be less than 50° C. In some embodiments, the temperature of the powered electrode and/or substrate during plasma deposition is less than about 40° C. or less than about 30° C. To control the temperature of the powered electrode, the electrode may be water-cooled or mounted on an insulating support with passageways for coolant. Cooling the powered electrode and substrate can increase the deposition rate. Also, at high temperatures, sometimes crystalline or semi-crystalline regions can form in the deposited layer, reducing the uniformity of the layer.

Using a high power density, power supply-pulsing, and a low temperature in the deposition of the amorphous, covalently-bonded layer are conditions useful for providing layer of uniform composition and a low degree of compressive stress. As a result, relatively thick layers (e.g., at least 5 micrometers thick) can be made on relatively large substrates (e.g., having a dimension of at least 50 millimeters).

Other methods may be useful for forming an amorphous, covalently-bonded layer on the substrate. For example, sputtering, evaporation techniques (laser evaporation), and cathodic arc deposition may be useful. However, plasma deposition under the conditions of ion bombardment is useful for forming sp³ bonded or diamond-like layers. Increasing the ion bombardment energy using the techniques described above can increase the proportion of the sp³ bonded atoms in the amorphous, covalently-bonded layer.

In some embodiments, before the amorphous, covalently-bonded layer is formed on the substrate, the substrate is treated by plasma priming (e.g., by oxygen or argon plasma). For example, the substrate may be primed with oxygen plasma under conditions of ion bombardment. Typically for plasma priming, power densities in the range from about 0.10 to about 0.95 watts/square cm can be applied. Also, typically for plasma priming, flow densities of the priming gas in the range from about 0.01 to about 1 sccm/square cm, in some embodiments 0.05 to 1 about sccm/square cm, and in some embodiments, about 0.1 to about 0.6 sccm/square cm can be applied. Before plasma priming, the surface of the substrate can also be solvent washed (e.g., with an organic solvent such as acetone or ethanol).

In some embodiments, before the amorphous, covalently-bonded layer is formed on the substrate, the substrate is treated by plasma etching (i.e., plasma cleaning). In some embodiments, a plasma etching step is useful, for example, for removing a thin film layer deposited on the plasma apparatus (e.g., electrodes) in a prior step. The gas that is used to generate an etching plasma typically includes oxygen gas and a fluorocarbon (e.g., CF₄, C₂F₆, or C₃F₈). The molar concentration of fluorocarbon gas in the mixture is typically 0 to 60% depending upon the particular type of fluorocarbon and on the composition of the deposited layer to be cleaned. More fluorocarbon percentage is needed if the fluorine:carbon ratio of the fluorocarbon is lower or if the silicon content of the deposited layer is higher. Argon can also be a useful gas for plasma etching in combination with at least one of oxygen or a fluorocarbon. Typically for plasma etching, power densities in the range from about 0.1 to about 1 watt/square cm can be applied. Also, typically for plasma etching, flow densities of the etching gas in the range from about 0.1 to about 1 sccm/square cm can be applied. Plasma etching or cleaning can also remove oils, other organic or silicon containing residual layers, and other contaminants from the substrate to be treated. In some embodiments of the method disclosed herein, plasma etching is integrated with plasma priming and plasma deposition. For example, plasma etching or cleaning can be used to clean the surface of the substrate. Oxygen gas can then be provided inside the apparatus under the conditions of plasma priming In some embodiments, an oxide layer is formed on the surface of the substrate during plasma priming Finally, a depositing plasma can be generated, for example, using source gas containing an organosilicon compound to provide an amorphous, covalently-bonded (in some embodiments, diamond-like glass) layer. In some cases, even if no fluorocarbon gas is used in depositing the amorphous, covalently-bonded layer, analysis of the layer can indicate the presence of fluorine due to residual fluorocarbon gas in the chamber from a previous plasma cleaning. For example, in Example 4, below, fluorine was observed in the amorphous, covalently-bonded layer by secondary ion mass spectrometry even though no fluorocarbon gas was used in the plasma deposition. In these embodiments, the amorphous, covalently-bonded layer may comprise on a hydrogen-free basis up to about 1, 0.5, 0.25, or 0.1 atomic percent fluorine.

The substrate in the article and method according to the present disclosure can be made from a wide variety of materials. In some embodiments, the substrate can be ceramic, metallic, or metalloid. Useful ceramic substrates include oxide and non-oxide ceramics (e.g., carbide, boride, silicide, or nitride ceramics) and crystalline (e.g., polycrystalline) and non-crystalline ceramics (e.g., glasses). In some embodiments, the substrate comprises at least one of silicon carbide, aluminum nitride, monocrystalline or polycrystalline aluminum oxide, or silicon nitride. In some embodiments, the substrate comprises at least one of silicon carbide, aluminum nitride, or silicon nitride. In some embodiments, the substrate is a polycrystalline ceramic. Useful metal and metalloid substrates include copper and silicon (e.g., silicon wafer semiconductors).

We have found that certain polycrystalline ceramics (e.g., silicon carbide) can be difficult to polish to a smooth finish. It is believed this is due to fine porosity in the material and to differences in material removal rates of different crystallographic orientations of individual grains during polishing. Using chemical mechanical planarization, we have been able to achieve a surface roughness (Ra) of a polycrystalline silicon carbide wafer as low as about 20 to 30 angstroms, but not as low as 15 angstroms or below. Achieving a surface roughness (Ra) of a polycrystalline silicon carbide wafer as low as about 20 to 30 angstroms was even time-consuming and difficult. Certain ceramics such as crystalline (e.g., polycrystalline) ceramics are substrates that typically have a surface roughness (Ra) of at least 100 angstroms, 500 angstroms, 750 angstroms, or at least 1000 angstroms even after surface grinding using diamond wheels optionally followed by double disk finishing.

In some embodiments, the substrate comprises a metal (e.g., a metal foil or metal plate). As received from a manufacturer, a metal foil (e.g., copper foil) can have a surface roughness in a range from 50 angstroms to 2500 angstroms.

Referring again to FIG. 1, the first surface roughness, which is the surface roughness (Ra) of surface 13 of the substrate 12 on which the amorphous, covalently-bonded layer 16 is disposed, is, in some embodiments, at least 100 angstroms. In some embodiments, the surface roughness (Ra) of surface 13 of the substrate 12 on which the amorphous, covalently-bonded layer 16 is disposed (that is, the first surface roughness) is at least 500 angstroms, 750 angstroms, or at least 1000 angstroms. In some embodiments, the surface roughness (Ra) of surface 13 of the substrate 12 on which the amorphous, covalently-bonded layer 16 is disposed is up to about 5000 angstroms, up to about 2500 angstroms, or up to about 2000 angstroms. For example, the surface roughness (Ra) of surface 13 of the substrate 12 on which the amorphous, covalently-bonded layer 16 is disposed may be in a range from 100 angstroms to 5000 angstroms, 100 angstroms to 2500 angstroms, 1000 angstroms to 5000 angstroms, or 1000 angstroms to 2500 angstroms.

In the article and method according to the present disclosure, the surface roughness (Ra) of surface 17 of the amorphous, covalently-bonded layer 16, which is the second surface roughness, is up to 15 angstroms. In some embodiments, the surface roughness (Ra) of surface 17 of the amorphous, covalently-bonded layer 16 (that is, the second surface roughness) is up to 10 angstroms, 8 angstroms, or up to 5 angstroms. For example, the surface roughness (Ra) of surface 17 of the amorphous, covalently-bonded layer 16 may be in a range from less than 1 angstrom to 15 angstroms, 1 angstrom to 10 angstroms, 1 angstrom to 8 angstroms, or 1 angstrom to 5 angstroms.

The surface roughness of both the substrate surface 13 and the surface 17 of the amorphous, covalently-bonded layer 16 is measured with a profilometer, for example, a profilometer manufactured by KLA-Tencor, Minneapolis, Minn., under the designation “HFP-200” on a 200 micrometer trace and using two or three different locations on the substrate. The surface roughness (Ra) is the arithmetic average of absolute values.

Once the amorphous, covalently-bonded layer is formed on the surface of the substrate, the first surface roughness, which is the surface roughness (Ra) of surface 13 of the substrate 12 on which the amorphous, covalently-bonded layer 16 is disposed, can readily be determined by subjecting the article to an etching plasma using the conditions described above. The gas that is used to generate an etching plasma typically includes oxygen gas and a fluorocarbon (e.g., CF₄, C₂F₆, or C₃F₈). In this way, if the surface roughness of the substrate before the formation of the amorphous, covalently-bonded layer is not known, the second surface roughness can be measured with a profilometer, and then the article can then be subjected to an etching plasma to remove the amorphous, covalently-bonded layer. The first surface roughness can then be measured with a profilometer.

The substrate may have a variety of useful sizes and shapes. For example, the substrate may be in the form of a wafer, in which one of its dimensions is small relative to its other two dimensions. In the plane that includes its larger dimensions, the substrate may have a rectangular, square, circular, or any other desirable shape. In some embodiments, the substrate has a dimension of at least 50 millimeters (mm). In some embodiments, the substrate has a dimension of at least 100 mm, 150 mm, or 200 mm. The dimension of at least 50, 100, 150, or 200 mm may be the largest dimension of the substrate and may be a side or a diameter, for example, depending on the shape of the substrate. The smallest dimension of the substrate may be up to 10, 9, 8, 7, 6, 5, 4, 3, 2, or 1 mm, in some embodiments.

In some embodiments, it is useful for the substrate to have relatively high thermal conductivity. In some embodiments, the thermal conductivity of the substrate is at least 100 watts per meter kelvin (W/m K). In some embodiments, the thermal conductivity of the substrate is at least 100, 110, 120, 130, 150, 200, 250, or 300 W/m K. Typically, and advantageously, the amorphous, covalently-bonded layer does not significantly change the thermal conductivity of the substrate. In some embodiments, the article has a thermal conductivity within ten (in some embodiments, 5, 4, 3, or 2) percent of the thermal conductivity of the substrate.

Thermal conductivities were measured for Examples 4 and 5, described below, and the results are shown in Table 2 in the Examples, below. These Examples demonstrate that the thermal conductivity of the substrate is not significantly decreased by the presence of the amorphous, covalently-bonded layer on its surface. Thus, articles according to the present disclosure can be useful, for example, in applications where heat dissipation is important.

In some embodiments, it is useful for the substrate to have relatively low electrical conductivity. In these embodiments, advantageously, the amorphous, covalently-bonded layer decreases the overall electrical conductivity of the article disclosed herein because it is an electrical insulator. In some embodiments, amorphous, covalently-bonded layer has an electrical resistivity of 10¹³ ohms/centimeter.

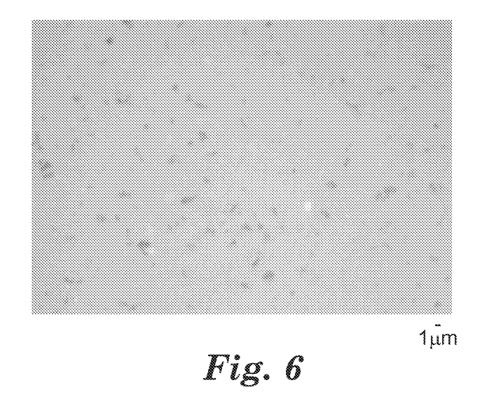

In some embodiments, the substrate is porous. For example, the substrate may be microporous having pore sizes up to about 100 micrometers or up to about 200 micrometers. A porous substrate can have average pore sizes, in some embodiments, in a range from 0.1 to 10 micrometers, 0.5 to 5 micrometers, or 1 to 50 micrometers. FIG. 6 illustrates a substrate under the amorphous, covalently-bonded layer having fine isolated fine porosity about 0.1 micrometers to about 2 micrometers in size.

In some embodiments, the substrate may have pore sizes up to about 100 micrometers or 200 micrometers in size with interconnected pores that occupy about 10% to 40% of the substrate volume. Such a substrate may allow gases or liquid (e.g., water vapor or liquid water) to be transmitted through the substrate. That is, the substrate is not hermetic. Advantageously, the amorphous, covalently-bonded layer can be deposited uniformly on surfaces having pore sizes up to about 200 micrometers. In some embodiments in which the substrate is porous (e.g., non-hermetic), the amorphous, covalently-bonded layer hermetically seals the substrate. The article including the substrate and the amorphous, covalently-bonded layer may have a water vapor transmission rate (WVTR) of less than about 0.05, 0.01, or 0.005 g/m²/day at 50° C. and 100% relative humidity, for example.

The amorphous, covalently-bonded layer on the surface of the substrate can be polished using conventional polishing techniques. For example, the amorphous, covalently-bonded layer may be polished by means of any polishing technique or combination thereof used in semiconductor industry. In some embodiments, the amorphous, covalently-bonded layer may be polished by Chemical Mechanical Planarization (CMP). The CMP process uses a very fine abrasive slurry in a chemically active medium in conjunction with a polishing pad and retaining ring, typically of a greater diameter than the substrate. The pad and substrate are pressed together by a dynamic polishing head and held in place by a plastic retaining ring. The dynamic polishing head is rotated with different axes of rotation (i.e., not concentric), while the polishing slurry is continuously supplied to an area between the substrate and the pad. This removes material and tends to even out any irregular topography. Various CMP polishing pads for use with abrasive slurries have been disclosed, for example, U.S. Pat. No. 5,257,478 (Hyde et al.); U.S. Pat. No. 5,921,855 (Osterheld et al.); U.S. Pat. No. 6,126,532 (Sevilla et al.); U.S. Pat. No. 6,899,598 (Prasad); and U.S. Pat. No. 7,267,610 (Elmufdi et al.). Fixed abrasive polishing pads are also known, as exemplified by U.S. Pat. No. 6,908,366 (Gagliardi), in which the abrasive particles are generally fixed to the surface of the pad, often in the form of precisely shaped abrasive composites extending from the pad surface.

Without wanting to be bound by theory, it is believed that the uniformity in thickness and composition and low porosity allow the amorphous, covalently-bonded layer to be polished to the surface roughness (Ra) of 15 angstroms or less. To polish the amorphous, covalently-bonded layer to achieve a surface roughness of up to 15, 10, 8, or 5 angstroms, it is typically useful for the amorphous, covalently-bonded layer to have a thickness of at least five (in some embodiments, at least 6, 7, 8, 9, or 10) micrometers. After polishing, the amorphous, covalently-bonded layer has a thickness of at least one micrometer. In some embodiments, after polishing, the amorphous, covalently-bonded layer typically has a thickness of at least two or three micrometers.

In some embodiments of the method according to the present disclosure, the surface of the substrate is ground or fine finished before the amorphous, covalently-bonded layer is formed on the surface of the substrate. This finishing typically provides a sufficiently flat surface over the entire substrate area and allows the amorphous, covalently-bonded layer to be evenly removed by CMP. A sufficiently flat surface typically has a flatness greater than the thickness of the deposited layer after polishing. Typically, these surface finishing steps can reduce the surface roughness of the substrate (first surface) to 100 angstroms or more.

Referring to the Examples, below, Example 1 demonstrates that an amorphous, covalently-bonded layer about 8 micrometers in thickness can be deposited on the surface of a silicon carbide substrate and that this layer is uniform in thickness and contains no porosity visible by a scanning electron microscope as shown in FIG. 4. Examples 2 and 3, below, demonstrate that the polishing quality achieved for the amorphous, covalently-bonded layer depends on the flatness of the substrate onto which the amorphous, covalently-bonded layer deposited on, the thickness of the layer applied to the substrate, and the total material removal achieved by polishing (e.g., CMP). Examples 2 and 3 also demonstrate that the surface roughness of the article according to the present disclosure, which includes the amorphous, covalently-bonded layer, is lower than the surface roughness of the substrate itself when the same CMP process is used. The Examples below also demonstrate that the amorphous, covalently-bonded layer can survive the polishing process without any evidence of chipping, flaking, or delamination.

Articles according to the present disclosure may be useful, for example, in complementary metal oxide semiconductor structures. Currently, in such applications, single crystal sapphire is typically used. Single crystal sapphire can be polished to a surface roughness Ra of 2 to 5 angstroms in some cases. As smaller and smaller structures are needed, the thermal conductivity of the sapphire becomes a limitation. Articles according to the present disclosure in which the substrate is a crystalline ceramic, for example, may be a useful replacement for sapphire in certain applications.

Articles according to the present disclosure may be useful for other applications. For example, when the substrate is a copper plate, an article disclosed herein may be useful as a heat spreader for various devices.

### Some Embodiments of the Disclosure

In a first embodiment, the present disclosure provides an article comprising:

a substrate having a surface with a first surface roughness (Ra) of at least 100 angstroms; and

an amorphous, covalently-bonded layer on the surface of the substrate, wherein the amorphous, covalently-bonded layer comprises silicon, oxygen, carbon, and hydrogen atoms, and wherein the amorphous, covalently-bonded layer has a second surface roughness (Ra) of up to 15 angstroms.

In a second embodiment, the present disclosure provides the article of the first embodiment, wherein the substrate has a dimension of at least 50 millimeters.

In a third embodiment, the present disclosure provides the article of the first or second embodiment, wherein the amorphous, covalently-bonded layer has a thickness of at least one micrometer.

In a fourth embodiment, the present disclosure provides the article of any one of the first to third embodiments, wherein the second surface roughness (Ra) is up to ten angstroms or up to five angstroms.

In a fifth embodiment, the present disclosure provides an article comprising:

a substrate having a dimension of at least 50 millimeters; and

an amorphous, covalently-bonded layer on a surface of the substrate, wherein the amorphous, covalently-bonded layer comprises silicon, oxygen, carbon, and hydrogen atoms and has a thickness of at least 5 micrometers.

In a sixth embodiment, the present disclosure provides the article of any one of the first to fifth embodiments, wherein the substrate is ceramic, metallic, or metalloid.

In a seventh embodiment, the present disclosure provides the article of the sixth embodiment, wherein the substrate comprises at least one of silicon carbide, aluminum nitride, monocrystalline or polycrystalline aluminum oxide, silicon nitride, copper, or silicon.

In an eighth embodiment, the present disclosure provides an article comprising:

a substrate comprising a crystalline ceramic; and

an amorphous, covalently-bonded layer on a surface of the substrate, wherein the amorphous, covalently-bonded layer comprises silicon, oxygen, carbon, and hydrogen atoms, and wherein the amorphous, covalently-bonded layer has a second surface roughness (Ra) of up to 15 angstroms.

In a ninth embodiment, the present disclosure provides the article of the eighth embodiment, wherein the substrate has a dimension of at least 50 millimeters.

In a tenth embodiment, the present disclosure provides the article of the eighth or ninth embodiment, wherein the amorphous, covalently-bonded layer has a thickness of at least one micrometer.

In an eleventh embodiment, the present disclosure provides the article of any one of the eighth to tenth embodiments, wherein the second surface roughness (Ra) is up to ten angstroms or up to five angstroms.

In a twelfth embodiment, the present disclosure provides the article of any one of the first to eleventh embodiments, wherein the substrate comprises at least one of silicon carbide, aluminum nitride, monocrystalline or polycrystalline aluminum oxide, or silicon nitride.

In a thirteenth embodiment, the present disclosure provides the article of the twelfth embodiment, wherein the substrate comprises at least one of silicon carbide, aluminum nitride, or silicon nitride.

In a fourteenth embodiment, the present disclosure provides the article of any one of the first to thirteenth embodiments, wherein the substrate is a polycrystalline ceramic.

In a fifteenth embodiment, the present disclosure provides the article of any one of the first to fourteenth embodiments, wherein the amorphous, covalently-bonded layer comprises diamond-like glass.

In a sixteenth embodiment, the present disclosure provides the article of any one of the first to fifteenth embodiments, wherein the amorphous, covalently-bonded layer comprises on a hydrogen-free basis at least about 30 atomic percent carbon, at least about 25 atomic percent silicon, and up to about 45 atomic percent oxygen.

In a seventeenth embodiment, the present disclosure provides the article of any one of the first to sixteenth embodiments, wherein the amorphous, covalently-bonded layer comprises on a hydrogen-free basis up to about one atomic percent fluorine.

In an eighteenth embodiment, the present disclosure provides the article of any one of the first to seventeenth embodiments, wherein the amorphous, covalently-bonded layer is essentially pore-free.

In a nineteenth embodiment, the present disclosure provides the articles of any one of the first to eighteenth embodiments, wherein the substrate has a first surface roughness (Ra) of at least 1000 angstroms.

In a twentieth embodiment, the present disclosure provides the article of any one of the first to twelfth embodiments, wherein article has a thermal conductivity within ten percent of a thermal conductivity of the substrate.

In a twenty-first embodiment, the present disclosure provides the article of any one of the first to twentieth embodiments, wherein the amorphous, covalently-bonded layer is covalently bonded to the substrate.

In a twenty-second embodiment, the present disclosure provides the article of any one of the first to twenty-first embodiments, wherein the substrate is a porous substrate.

In a twenty-third embodiment, the present disclosure provides the article of the twenty-second embodiment, wherein the amorphous, covalently-bonded layer hermetically seals the porous substrate.

In a twenty-fourth embodiment, the present disclosure provides a method of making an article, the method comprising:

providing a substrate having a surface;

forming an amorphous, covalently-bonded layer comprising silicon, oxygen, carbon, and hydrogen atoms on the surface of the substrate by plasma deposition; and

polishing the amorphous, covalently-bonded layer to a second surface roughness (Ra) of up to 15 angstroms.

In a twenty-fifth embodiment, the present disclosure provides the method of the twenty-fourth embodiment, wherein the substrate has a dimension of at least 50 millimeters.

In a twenty-sixth embodiment, the present disclosure provides the method of the twenty-fourth or twenty-fifth embodiments, wherein before polishing, the amorphous, covalently-bonded layer has a thickness of at least five micrometers.

In a twenty-seventh embodiment, the present disclosure provides the method of any one of the twenty-fourth to twenty-sixth embodiments, wherein after polishing, the amorphous, covalently-bonded layer has a thickness of at least one micrometer.

In a twenty-eighth embodiment, the present disclosure provides the method of any one of the twenty-fourth to twenty-seventh embodiments, wherein the second surface roughness (Ra) is up to ten angstroms.

In a twenty-ninth embodiment, the present disclosure provides method of the twenty-eighth embodiments, wherein the second surface roughness (Ra) is up to five angstroms.

In a thirtieth embodiment, the present disclosure provides a method of making an article, the method comprising:

providing a substrate having a surface and a dimension of at least 50 millimeters; and

forming an amorphous, covalently-bonded layer comprising silicon, oxygen, carbon, and hydrogen atoms on the surface of the substrate by plasma deposition, wherein the amorphous, covalently-bonded layer and has a thickness of at least 5 micrometers.

In a thirty-first embodiment, the present disclosure provides the method any one of the twenty-fourth to thirtieth embodiments, wherein the substrate has a first surface roughness (Ra) of at least 100 angstroms.

In a thirty-second embodiment, the present disclosure provides the method of the thirty-first embodiment, wherein the substrate has a first surface roughness (Ra) of at least 1000 angstroms.

In a thirty-third embodiment, the present disclosure provides the method of any one of the twenty-fourth to thirty-second embodiments, wherein the amorphous, covalently-bonded layer comprises diamond-like glass.

In a thirty-fourth embodiment, the present disclosure provides the method of any one of the twenty-fourth to thirty-third embodiments, wherein the amorphous, covalently-bonded layer comprises on a hydrogen-free basis at least about 30 atomic percent carbon, at least about 25 atomic percent silicon, and up to about 45 atomic percent oxygen.

In a thirty-fifth embodiment, the present disclosure provides the method of any one of the twenty-fourth to thirty-fourth embodiments, wherein the amorphous, covalently-bonded layer comprises on a hydrogen-free basis up to about one atomic percent fluorine.

In a thirty-sixth embodiment, the present disclosure provides the method of any one of the twenty-fourth to thirty-fifth embodiments, wherein article has a thermal conductivity within ten percent of a thermal conductivity of the substrate.

In a thirty-seventh embodiment, the present disclosure provides the method of any one of the twenty-fourth to thirty-sixth embodiments, wherein the amorphous, covalently-bonded layer is covalently bonded to the substrate.

In a thirty-eighth embodiment, the present disclosure provides the method of any one of the twenty-fourth to thirty-seventh embodiments, wherein the substrate is ceramic, metallic, or metalloid.

In a thirty-ninth embodiment, the present disclosure provides the method of the thirty-eighth embodiment, wherein the substrate comprises at least one of silicon carbide, aluminum nitride, monocrystalline or polycrystalline aluminum oxide, silicon nitride, copper, or silicon.

In a fortieth embodiment, the present disclosure provides the method of the thirty-ninth embodiment, wherein the substrate comprises at least one of silicon carbide, aluminum nitride, monocrystalline or polycrystalline aluminum oxide, or silicon nitride.

In a forty-first embodiment, the present disclosure provides the method of the fortieth embodiment, wherein the substrate comprises at least one of silicon carbide, aluminum nitride, or silicon nitride.

In a forty-second embodiment, the present disclosure provides the method of the thirty-eighth embodiment, wherein the substrate is a crystalline ceramic, in some embodiments, a polycrystalline ceramic.

In a forty-third embodiment, the present disclosure provides the method of any one of the twenty-fourth to forty-second embodiments, wherein the substrate is a porous substrate.

In a forty-fourth embodiment, the present disclosure provides the method of the forty-third embodiment, wherein the amorphous, covalently-bonded layer hermetically seals the porous substrate.

In a forty-fifth embodiment, the present disclosure provides the method of any one of the twenty-fourth to forty-fourth embodiments, wherein forming the amorphous, covalently-bonded layer comprises ionizing a gas comprising at least one of an organosilicon or a silane compound.

In a forty-sixth embodiment, the present disclosure provides the method of the forty-fifth embodiment, wherein the gas comprises the organosilicon, and wherein the organosilicon comprises tetramethylsilane.

In a forty-seventh embodiment, the present disclosure provides the method of the forty-fifth or forty-sixth embodiment, wherein the gas further comprises oxygen.

In a forty-eighth embodiment, the present disclosure provides the method of any one of the forty-fifth to forty-seventh embodiments, wherein the gas is free of fluorinated compounds, or wherein the gas comprises a fluorinated compound at up to 1 molar percent of the gas.

In a forty-ninth embodiment, the present disclosure provides the method of any one of the twenty-fourth to forty-eighth embodiments, wherein the plasma deposition of the amorphous, covalently-bonded layer is carried out for a period of time of at least about ten minutes.

In a fiftieth embodiment, the present disclosure provides the method of any one of the twenty-fourth to forty-ninth embodiments, wherein the plasma deposition of the amorphous, covalently-bonded layer is carried out at a temperature of up to 50° C.

In a fifty-first embodiment, the present disclosure provides the method of any one of the twenty-fourth to fiftieth embodiments, wherein a powered electrode is pulsed on and off during the plasma deposition of the amorphous, covalently-bonded layer.

In a fifty-second embodiment, the present disclosure provides the method of any one of the twenty-fourth to fifty-first embodiments, wherein the plasma deposition of the amorphous, covalently-bonded layer is carried out at a power density of at least 1 watt per square centimeter.

In a fifty-third embodiment, the present disclosure provides the method of any one of the twenty-fourth to fifty-second embodiments, wherein before forming the amorphous, covalently-bonded layer comprising silicon, oxygen, carbon, and hydrogen atoms on the surface of the substrate by plasma deposition, the substrate is exposed to an oxygen plasma.

In a fifty-fourth embodiment, the present disclosure provides the method of any one of the twenty-fourth to fifty-third embodiments, wherein polishing comprises chemical mechanical planarization.

In order that this disclosure can be more fully understood, the following examples are set forth. It should be understood that these examples are for illustrative purposes only and are not to be construed as limiting this disclosure in any manner

### EXAMPLES

### Example 1

Hot pressed silicon carbide plates with dimensions of 100 mm by 100 mm by 9 mm were obtained from Ceradyne, Inc., Costa Mesa, Calif., under the trade designation “CERALLOY 146-IS”. The top and bottom surfaces of the plates were surface ground with a 320 grit diamond wheel until the plate was flat and parallel within 0.001 inch (0.0254 mm).

A commercial parallel-plate capacitively coupled plasma reactor (commercially available as Model 2480 from PlasmaTherm of St. Petersburg, Fla.), typically used for reactive ion etching, was used to carry out a plasma treatment of a silicon carbide plate. The reactor had a chamber that was cylindrical in shape with an internal diameter of 762 mm (30 inches) and height of 150 mm (6 inches) and a circular powered electrode having a diameter of 686 mm (27 inches) mounted inside the chamber. The powered electrode was attached to a matching network and a 3 kW RF power supply that was operated at a frequency of 13.56 MHz. The powered electrode was water-cooled with water at room temperature. The chamber was vacuum pumped with a roots blower backed by a mechanical pump. Unless otherwise stated, the base pressure in the chamber was 0.67 Pa (5 mTorr). Process gases were metered into the chamber either through mass flow controllers or a needle valve. Unless otherwise stated, all the plasma treatments were done with the sample located on the powered electrode of the plasma reactor.

The silicon carbide plate was subjected to a preliminary plasma treatment of oxygen alone at a flow rate of 500 standard cubic centimeters per minute (SCCM) and power of 1000 watts for one minute with the plasma pulsing at a frequency of 10 Hz with the plasma “on-time” at 80 milliseconds and “off-time” of 20 milliseconds Immediately after the oxygen plasma cleaning step, tetramethylsilane vapor was introduced into the chamber at a flow rate of 360 sccm, and the oxygen flow was dropped to 100 sccm. The plasma power conditions were maintained the same at 1000 watts with the plasma pulsing at a frequency of 10 Hz, with a plasma “on-time” of 80 milliseconds and “off-time” of 20 milliseconds. The plasma deposition step was continued for 20 minutes. After this, the plasma power was disabled, the gases shut off, and the chamber vented to atmospheric pressure. The SiC wafer with the DLC film was removed from the chamber upon venting. Referring to FIG. 2, since the silicon carbide plate was placed flat on the electrode 26, the amorphous, covalently-bonded layer was formed on only one side of the plate.

The thickness of the amorphous, covalently-bonded layer was measured by interferometry and estimated to be in a range from 6 to 8 micrometers (μm) on most of the plate except for areas about 5 to 10 mm from the plate's edge. It was observed that the amorphous, covalently-bonded layer did not adhere well in some areas close to the edge of the plate.

A well-coated area of the plate was fractured, and the treated side of the plate was examined using a Scanning Electron Microscope S-3400N from Hitachi High-Technologies Corporation (Tokyo, Japan). Scanning electron imaging was carried out using 20 KV accelerating voltage. A micrograph of the fractured plate is shown in FIG. 4, with amorphous, covalently-bonded layer 16 disposed on a substrate 12. As shown in FIG. 4, the thickness of the amorphous, covalently-bonded layer 16 observed on the fracture surface was about 8 μm. FIG. 4 also shows the amorphous, covalently-bonded layer 16 is uniform in composition and thickness, contains only one visible phase, and has no porosity detectable by SEM. Substrate 12 has some porosity (from about 0.1 μm to about 2 μm) and more than one phase as shown in FIG. 4.

Energy dispersive spectroscopy, performed during the analysis with the scanning electron microscope of the amorphous, covalently-bonded layer indicated the presence of carbon, oxygen, and silicon.

X-ray diffraction patterns were collected on a section of the silicon carbide plate on both the treated side and the untreated side. A bench top X-ray diffraction instrument model “MINIFLEX” from Rigaku (Tokyo, Japan) using Cu K-α-Si₃N₄ radiation. The pattern was collected from 25 to 55 2-theta angles. The X-ray diffraction patterns of both sides of the plate gave identical patterns showing only 4H and 6H silicon carbide phases and a trace of graphite, all coming from the substrate. No evidence of additional crystalline phases in the deposited layer was observed, suggesting that the layer was amorphous.

The treated plate can be polished as shown in Examples 2 and 3, below.

### Example 2

For Example 2, a substrate was prepared and an amorphous, covalently-bonded layer was deposited on the substrate as described in Example 1 with the modification that aluminum plates were stacked up against the edges of each side of the substrate the substrate. The surface of the substrate to be treated was the same height as the aluminum plates surrounding it. The use of the holder resulted in the deposited amorphous, covalently-bonded extending more uniformly to the edges of the substrate relative to Example 1. The thickness of the amorphous, covalently-bonded layer was measured to be 6 μm to 8 μm, including at the edges, by interferometry.

The surface roughness (Ra) of the amorphous, covalently-bonded layer was about 900 angstroms as determined using a profilometer manufactured by KLA-Tencor, Minneapolis, Minn., under the designation “HFP-200” on a 200-μm trace and using an average of three measurements in three locations. Using the same method, the surface roughness (Ra) of the uncoated side of the substrate was measured and was determined to be about 990 angstroms. The uncoated side was then ground with a 600 grit diamond wheel to a surface roughness of 590 angstroms with better flatness.

The sample was then sent to Axus Technology, Chandler, Ariz., where both the amorphous, covalently-bonded layer and untreated sides of the substrate were polished using Chemical Mechanical Planarization (CMP). The untreated side was subjected to initial CMP steps while the amorphous, covalently-bonded layer was subjected to further CMP steps. The polished surface roughness of the amorphous, covalently-bonded layer was measured to be 10.6 angstroms using a profilometer manufactured by KLA-Tencor under the designation “HFP-200” on a 200-μm trace. Initial CMP steps improved the surface roughness of the uncoated side to an Ra of 56 angstroms as determined using a the same method.

The surface roughness of the amorphous, covalently-bonded layer after CMP was also measured using an atomic force microscope (model Nano-R, from Pacific Nanotechnology, Inc., Phoenix, Ariz.) using a Si tip and near contact method with a 10 μm×10 μm areal scan. The average surface roughness Sa was determined to be 15 angstroms, with selected area roughness Sa values in a range from 5 angstroms to 16 angstroms. Examination of the surfaces of the amorphous, covalently-bonded layer after CMP revealed that in many areas the substrate did not have any of the amorphous, covalently-bonded layer remaining on its surface. In these areas, the surface roughness (Sa) was in a range from 15 to 20 angstroms. An optical micrograph of one of these areas, which reveals surface porosity, is shown in FIG. 6. In areas in which the amorphous, covalently-bonded layer was still on the surface the surface roughness (Sa) was under 15 angstroms.

### Example 3

For Example 3, a substrate was prepared and an amorphous, covalently-bonded layer was deposited on the substrate as described in Example 2 with the modification that a longer plasma deposition time of 30 minutes was used. As a result the thickness of the amorphous, covalently-bonded layer was determined to be 10 μm to 12 μm using interferometry. Using the profilometer method described in Example 2, the surface roughness Ra of the uncoated side of the substrate was measured to be 925 angstroms, and a surface roughness of 498 angstroms with a better flatness was achieved after grinding The sample was then sent to Axus Technology, Chandler, Ariz., where both the coated and uncoated sides of the substrate were polished using CMP. CMP was carried out on the uncoated side for about half of the length of time CMP was carried out on the amorphous, covalently-bonded layer. CMP of the uncoated side provided a surface roughness Ra of 34 angstroms, and the final surface roughness of the amorphous, covalently-bonded layer after CMP was 6 angstroms as measured using the profilometer method described in Example 2. Microscopic examination confirmed that the amorphous, covalently-bonded layer remained on the substrate after polishing.

### Example 4

Hot pressed silicon carbide wafers with dimensions of 200 mm in diameter and 1 to 2 mm in thickness were obtained from Ceradyne, Inc., under the trade designation “CERALLOY 146-IS”. Both sides of the wafers were surface ground with 320 grit wheel to 0.8 mm in thickness. Both sides of the wafers were then fine ground to a 2 μm to 3 μm flatness and a surface roughness Ra of about 570 angstroms.

The wafers were then plasma treated according to the method of Example 3 (using a deposition time of 30 minutes and a wafer holder during deposition such as that shown in FIG. 3) to provide an amorphous, covalently-bonded layer, which was measured to be in a range from ten to 12 μm using interferometry.

The sample was then sent to Axus Technology where the amorphous, covalently-bonded layer was polished using Chemical Mechanical Planarization (CMP). During planarization, care was taken to ensure that the amorphous, covalently-bonded layer remained at least two μm to three μm thick in all locations.

The surface roughness of the amorphous, covalently-bonded layer on 3 of the 6 wafers was measured after CMP using an interferometer obtained from Zygo Corporation, Middlefield, Conn., under the trade designation “ZYGO NEXVIEW” on a 58 μm×58 μm scan area. Surface roughness Sa of 6.6 angstroms; 7.3 angstroms, and 6.8 angstroms were measure in the center of the wafer, and similar values were obtained close to the wafer edge.

Additionally, the surface roughness of the amorphous, covalently-bonded layer was measured after CMP using an atomic force microscope obtained from Bruker Corporation, Billerica, Mass., under the trade designation “DIMENSION 3100 NANOSCOPE V”. The measurement was done in tapping mode using Si probes on 2 μm², 5 μm², and 50 μm² scan areas. Sa and Sq values for each of these scan lengths is shown Table 1 as an average of three measurements with the standard deviation.

TABLE 1

| Scan Size | Sa (angstroms) | Sq (angstroms) |
|---|---|---|
| 2 μm² | 2.3 ± 0.5 | 3.7 ± 0.5 |
| 5 μm² | 4.5 ± 0.4 | 5.9 ± 0.7 |
| 50 μm² | 5.5 ± 1.2 | 16.2 ± 0.8 |

The amorphous, covalently-bonded layer was observed to be transparent by optical microscopy. After CMP, one of the wafers was fractured, and a cross-section of the wafer with the amorphous, covalently-bonded layer was examined using a scanning electron microscope as described in Example 1. Using backscattered imaging, the amorphous, covalently-bonded layer was found to be in a range from 3 μm to 4 μm thick. The layer was uniform and of a single phase with no visible porosity by scanning electron microscopy. A micrograph of the polished surface of the amorphous, covalently-bonded layer is shown in FIG. 5.

Auger analysis was carried out on the amorphous, covalently-bonded layer during argon sputtering of 1 μm of the layer using a PerkinElmer PHI-660 Scanning Electron Microprobe (obtained from PerkinElmer, Waltham, Mass.). The analysis showed a consistent chemical composition of the layer with about 39 atomic % carbon, 35 atomic % silicon, and 26 atomic % oxygen. The Auger spectra for the layer at the beginning and end of the sputtering were similar with silicon and carbon peak positions consistent with sp³ bonding. An Auger spectrum of a silicon carbide single crystal was also obtained after sputtering off 1 μm. The peak positions for silicon and carbon in the silicon carbide were very similar to those in the amorphous, covalently-bonded layer, also indicating sp³ bonding.

Secondary ion mass spectrometry (SIMS) and X-ray photoelectron spectroscopy (XPS) elemental profiles during sputtering were also obtained. Sputtering was done through the entire amorphous, covalently-bonded layer and continued into the silicon carbide wafer.

For SIMS, time of flight SIMS was carried out with an instrument obtained from ION-TOF GmbH, Münster, Germany, under the trade designation “TOF.SIMS 5” by sampling a 500 μm by 500 μm area and sputtering with a 2 keV O₂⁺ ion beam with a diameter of about 3 μm. Mass spectra of the amorphous, covalently-bonded layer confirmed presence of carbon, silicon, and oxygen in the coating and also indicated presence of some hydrogen and fluorine, which is to be expected based on the gases used during the wafer plasma deposition preceded by plasma cleaning. Levels of F-, C₄-, SiC-, C₂-, and H-ions show large shifts after sputtering off the amorphous layer and getting into the silicon carbide wafer.

XPS spectra (Physical Electronics VERSAPROBE 5000 instrument obtained from Physical Electronics, Chanhassen, Minn.) provided a third independent verification that the amorphous, covalently-bonded layer contains C, O and Si. Sputtering using Ar ions of a 200 μm diameter area also confirmed a consistent composition of the coating throughout the thickness of the amorphous, covalently-bonded layer.

### Example 5

Several rectangular thin samples of silicon carbide about 2 mm thick were machined from hot pressed silicon carbide plates with dimensions of 100 mm by 100 mm by 9 mm, obtained from Ceradyne, Inc., under the trade designation “CERALLOY 146-IS”. For one sample, an amorphous, covalently-bonded layer about 8 μm thick was formed on one surface using plasma deposition as described in Example 1. For a second sample, an amorphous, covalently-bonded layer about 8 μm thick was formed on both surfaces using plasma deposition as described in Example 1. A third sample was not coated and served as a reference.

The thermal conductivity of the three samples was then measured using an instrument obtained from Netzsch-Gerätebau GmbH, Selb, Germany, under the trade designation “LFA447 NANOFLASH”. The results are shown in Table 2, below.

TABLE 2

| | | Thermal |
|---|---|---|
| | Density | Conductivity |
| Example | (g/cm³) | (W/m K) |
| Example 5, untreated | 3.04 | 122 |
| Example 5, one side treated | 3.04 | 120 |
| Example 5, two sides treated | 3.02 | 118 |
| Example 4 | 3.16 | 137 |

A wafer from Example 4, having an amorphous, covalently-bonded layer about 3 μm to 4 μm in thickness than had been polished by CMP was also machined into a rectangular sample. The thermal conductivity was measured, and the results are shown in Table 2, above. An untreated wafer had a thermal conductivity of about 140 W/m K.

### Example 6

A wafer made from dense hot pressed aluminum nitride obtained from Ceradyne, Inc., under the trade designation “CERALLOY 1370-CS” with dimensions of 38.1 mm by 38.1 mm by 0.51 mm (1.5 inches by 1.5 inches by 0.2 inches) was ground on both sides using a 180 grit wheel, and an amorphous, covalently-bonded layer was deposited on one side using the procedure described in Example 1. The coated side of the wafer was examined by optical microscopy and was found to be transparent, allowing the surface of the polished aluminum nitride wafer to be seen under the amorphous, covalently-bonded layer.

The coated wafer was fractured, and the fracture surface examined with a scanning electron microscope as described in Example 1. The thickness of the amorphous, covalently-bonded layer was uniform and was measured to be 7 μm to 8 μm thick. The interface between the amorphous, covalently-bonded layer and the aluminum nitride substrate was continuous along the fracture surface with no discontinuities or evidence of delamination. The interface appeared very similar to that shown in FIG. 4. The amorphous, covalently-bonded layer was uniform composition and thickness, contained only one visible phase, and had no porosity detectable by SEM. The substrate had some fine, isolated porosity up to about 3 μm in size and more than one phase: aluminum nitride and the sintering aid phase at the grain boundaries.

CMP polishing can be used to polish the amorphous, covalently-bonded layer as described in Example 4, above.

This disclosure may take on various modifications and alterations without departing from its spirit and scope. Accordingly, this disclosure is not limited to the above-described embodiments but is to be controlled by the limitations set forth in the following claims and any equivalents thereof. This disclosure may be suitably practiced in the absence of any element not specifically disclosed herein. All patents and patent applications cited above are hereby incorporated by reference into this document in their entirety.

1. An article comprising:
a substrate having a surface with a first surface roughness (Ra) of at least 100 angstroms; and
an amorphous, covalently-bonded layer on the surface of the substrate, wherein the amorphous, covalently-bonded layer comprises silicon, oxygen, carbon, and hydrogen atoms, and wherein the amorphous, covalently-bonded layer has a second surface roughness (Ra) of up to 15 angstroms.

2. The article of claim 1, wherein the substrate comprises at least one of silicon carbide, aluminum nitride, monocrystalline or polycrystalline aluminum oxide, silicon nitride, copper, or silicon.

3. An article comprising:
a substrate comprising a crystalline ceramic; and
an amorphous, covalently-bonded layer on a surface of the substrate, wherein the amorphous, covalently-bonded layer comprises silicon, oxygen, carbon, and hydrogen atoms, and wherein the amorphous, covalently-bonded layer has a second surface roughness (Ra) of up to 15 angstroms.

4. An article comprising:
a substrate having a dimension of at least 50 millimeters; and
an amorphous, covalently-bonded layer on a surface of the substrate, wherein the amorphous, covalently-bonded layer comprises silicon, oxygen, carbon, and hydrogen atoms and has a thickness of at least 5 micrometers.

5. The article of claim 1, wherein the amorphous, covalently-bonded layer comprises diamond-like glass.

6. The article of claim 1, wherein the amorphous, covalently-bonded layer comprises on a hydrogen-free basis at least about 30 atomic percent carbon, at least about 25 atomic percent silicon, and up to about 45 atomic percent oxygen.

7. The article of claim 1, wherein the article has a thermal conductivity within ten percent of a thermal conductivity of the substrate.

8. The article of claim 1, wherein the amorphous, covalently-bonded layer is covalently bonded to the substrate.

9. The article of claim 1, wherein the substrate is a porous substrate, and wherein the amorphous, covalently-bonded layer hermetically seals the porous substrate.

10. A method of making the article of claim 1, the method comprising:
providing the substrate having the surface with the first surface roughness (Ra) of at least 100 angstroms;
forming the amorphous, covalently-bonded layer comprising silicon, oxygen, carbon, and hydrogen atoms on the surface of the substrate by plasma deposition; and
polishing the amorphous, covalently-bonded layer to the second surface roughness (Ra) of up to 15 angstroms.

11. The method of claim 10, wherein before polishing, the amorphous, covalently-bonded layer has a thickness of at least five micrometers.

12. A method of making the article of claim 4, the method comprising:
providing the substrate having the dimension of at least 50 millimeters; and
forming the amorphous, covalently-bonded layer comprising silicon, oxygen, carbon, and hydrogen atoms on the surface of the substrate by plasma deposition, wherein the amorphous, covalently-bonded layer and has a thickness of at least 5 micrometers.

13. The method of claim 12, wherein the substrate has a first surface roughness (Ra) of at least 100 angstroms.

14. The method of claim 10, wherein forming the amorphous, covalently-bonded layer comprises ionizing a gas comprising at least one of an organosilicon or a silane compound.

15. The method of claim 10, wherein a powered electrode is pulsed on and off during the plasma deposition of the amorphous, covalently-bonded layer, and wherein the plasma deposition of the amorphous, covalently-bonded layer is carried out at a power density of at least 0.2 watt per square centimeter.

16. The article of claim 3, wherein the amorphous, covalently-bonded layer comprises diamond-like glass.

17. The article of claim 3, wherein the amorphous, covalently-bonded layer comprises on a hydrogen-free basis at least about 30 atomic percent carbon, at least about 25 atomic percent silicon, and up to about 45 atomic percent oxygen.

18. The article of claim 3, wherein the article has a thermal conductivity within ten percent of a thermal conductivity of the substrate.

19. The article of claim 3, wherein the amorphous, covalently-bonded layer is covalently bonded to the substrate.

20. The article of claim 3, wherein the substrate is a porous substrate, and wherein the amorphous, covalently-bonded layer hermetically seals the porous substrate.
